(19) United States
(12) Patent Application Publication
(10) Pub. No.: US 2015/0036292 A1
(43) Pub. Date: Feb. 5, 2015

(54) Electrical Device for Use in an Automotive Vehicle and Method for Cooling Same

(71) Applicant: Lear Corporation, Southfield, MI (US)

(72) Inventors: Rutunj Rai, Canton, MI (US); Krzysztof Klesyk, Novi, MI (US); Arthur L. Richards, Livonia, MI (US)

(73) Assignee: Lear Corporation, Southfield, MI (US)

(21) Appl. No.: 13/956,634

(22) Filed: Aug. 1, 2013

(51) Int. Cl. H05K 1/02; H05K 5/02

(52) U.S. Cl. CPC H05K 1/0203; H05K 5/0213; H05K 2201/064
USPC 361/692

(57) ABSTRACT

An electrical device is described for use in an automotive vehicle. The device includes a printed circuit board (PCB) having first and second sides. The PCB is adapted for multiple electronic components to be mounted to the first side, including a first component at a first position and a second component at a second position. The second component is capable of substantially blocking airflow directed substantially across the first side from at least one direction toward the first component. The PCB defines a plurality of apertures formed in a region of the PCB including the first position such that airflow directed substantially across the second side of the PCB flows through the apertures, under the first component at the first position on the first side of the PCB, and on a portion of the first side of the PCB beyond the region of the PCB including the first position.

### TECHNICAL FIELD

The following relates to an electrical device, such as an inverter, for use in an automotive vehicle and a method for cooling such a device.

### BACKGROUND

Automotive vehicles, whether powered by an internal combustion engine alone, or by an electric motor or an electric motor and an internal combustion engine combination, which are commonly referred to as electric vehicles (EV) or hybrid-electric vehicles (HEV), include batteries for supplying electric power to electrical components and/or the electric motors thereof.

To do so, such vehicles include an inverter for use in converting the direct current (DC) voltage provided by a vehicle battery or batteries to an alternating current (AC) voltage for use in powering the electrical components and/or electric motor or motors of the vehicle. Such an inverter may comprise multiple electrical or electronic components. Such components may include switching modules, such as transistor modules, as well as capacitors, transformers and/or other components.

In converting an input DC voltage to an AC voltage output, such components, particularly transformers, generate heat as a result of their operation. The heat generated as a result of such operation should be dissipated so that the components and/or device may continue to operate efficiently. The heat generated by such operation may be dissipated using a coolant, such as air, directed to flow past such components.

In that regard, an exemplary cooling device for use in electric or hybrid-electric vehicles is shown in U.S. Pat. No. 7,079,379 entitled “Cooling Device High Voltage Electrical unit For Motor Of Vehicle, And Hybrid Vehicle.” Additional exemplary devices and various features thereof are shown in U.S. Pat. No. 7,218,517 entitled “Cooling Apparatus For Vertically Stacked Printed Circuit Boards,” U.S. Pat. No. 7,535,707 entitled “Power Supply Cooling System,” U.S. Pat. No. 7,819,172 entitled “Cooling Apparatus For Vehicle Electrical Packaging Unit,” and U.S. Patent Application Publication No. 2011/0134610 entitled “Electronic Module.”

However, due to the high heat generated as a result of the operation of an inverter or any other electrical device with high heat generation used in such vehicles, there exists a need for improved heat dissipation beyond that which may be provided by standard devices and/or methods currently in use with such devices. Such an improved electrical device and cooling method would include a printed circuit board (PCB) having multiple apertures formed therein and directing airflow substantially across a first side of the PCB so that air flows through the apertures under an electrical component on a second side of the PCB and beyond that component on the second side of the PCB.

### SUMMARY

According to one embodiment disclosed herein, an electrical device is provided for use in an automotive vehicle. The device comprises a printed circuit board (PCB) having a first side and a second side, and a plurality of electronic components mounted to the first side of the PCB. The components comprise a first component located at a first position on the first side of the PCB and a second component located at a second position on the first side of the PCB, the second component located at the second position capable of at least partially blocking airflow directed substantially across the first side of the PCB from at least one direction toward the first component. The PCB defines a plurality of apertures therethrough, the apertures formed in a region of the PCB comprising the first position such that airflow directed substantially across the second side of the PCB flows through the apertures, under the first component at the first position on the first side of the PCB, and on at least a portion of the first side of the PCB beyond the region of the PCB comprising the first position.

According to another embodiment disclosed herein, an electrical device is provided for use in an automotive vehicle. The device comprises a printed circuit board (PCB) having a first side and a second side, the PCB adapted for a plurality of electronic components to be mounted to the first side thereof. The components comprise a first component to be located at a first position on the first side of the PCB and a second component to be located at a second position on the first side of the PCB, the second component to be located at the second position capable of at least partially blocking airflow directed substantially across the first side of the PCB from at least one direction toward the first component. The PCB defines a plurality of apertures therethrough, the apertures formed in a region of the PCB comprising the first position such that airflow directed substantially across the second side of the PCB flows through the apertures, under the first component at the first position on the first side of the PCB, and on at least a portion of the first side of the PCB beyond the region of the PCB comprising the first position.

According to a further embodiment disclosed herein, a method is provided for cooling an electrical device for use in an automotive vehicle. The inverter comprises a printed circuit board (PCB) having a first side and a second side, and a plurality of electronic components mounted to the first side of the PCB. The components comprise a first component located at a first position on the first side of the PCB and a second component located at a second position on the first side of the PCB, the second component located at the second position capable of at least partially blocking airflow directed substantially across the first side of the PCB from at least one direction toward the first component. The PCB defines a plurality of apertures therethrough, the apertures formed in a region of the PCB comprising the first position. The method comprises directing airflow substantially across the second side of the PCB so that air flows through the apertures, under the first component at the first position on the first side of the PCB, and on at least a portion of the first side of the PCB beyond the region of the PCB comprising the first position.

A detailed description of these embodiments of an electrical device for use in an automotive vehicle, and a method for cooling such a device, are set forth below together with accompanying drawings.

### BRIEF DESCRIPTION OF THE DRAWINGS

FIG. 1 is a perspective view of an inverter for use in an automotive vehicle, including a printed circuit board and multiple electrical or electronic components mounted on one side thereof, as disclosed herein;

FIG. 2 is another perspective view of an inverter for use in an automotive vehicle, including a printed circuit board and multiple electrical or electronic components mounted on one side thereof, as disclosed herein;

FIG. 3 is another perspective view of an inverter for use in an automotive vehicle, including a printed circuit board having apertures formed therein, as disclosed herein; and

FIG. 4 is a perspective view an inverter for use in an automotive vehicle, including a housing adapted to receive a printed circuit board and multiple electrical or electronic components mounted thereto, as disclosed herein.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

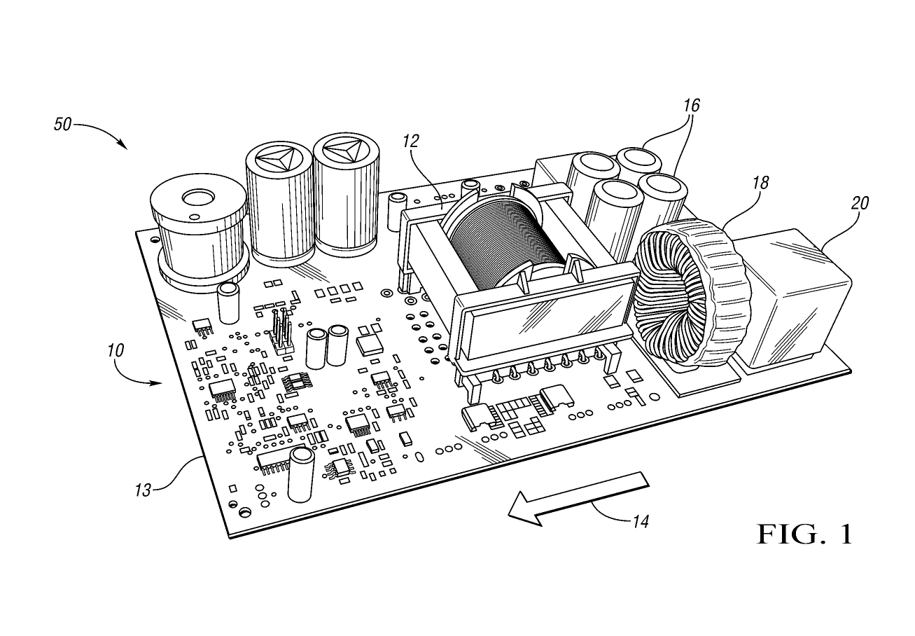

With reference to FIGS. 1-4, a more detailed description of embodiments of an electrical device for use in an automotive vehicle and a method for cooling such a device will be described. For ease of illustration and to facilitate understanding, like reference numerals have been used herein for like components and features throughout the drawings.

As noted above, automotive vehicles, whether powered by an internal combustion engine alone, or by an electric motor or an electric motor and an internal combustion engine combination, which are commonly referred to as electric vehicles (EV) or hybrid-electric vehicles (HEV), include batteries for supplying electric power to electrical components and/or the electric motors thereof.

To do so, such vehicles include an inverter for use in converting the direct current (DC) voltage provided by a vehicle battery or batteries to an alternating current (AC) voltage for use in powering the electrical components and/or electric motor or motors of the vehicle. Such an inverter may comprise multiple electrical or electronic components. Such components may include switching modules, such as transistor modules, as well as capacitors, transformers and/or other components.

In converting an input DC voltage to an AC voltage output, such components, particularly transformers, generate heat as a result of their operation. The heat generated as a result of such operation should be dissipated so that the components and/or device may continue to operate efficiently. The heat generated by such operation may be dissipated using a coolant, such as air, directed to flow past such components.

In that regard, an exemplary cooling device for use in electric or hybrid-electric vehicles is shown in U.S. Pat. No. 7,079,379 entitled “Cooling Device High Voltage Electrical unit For Motor Of Vehicle, And Hybrid Vehicle.” Additional exemplary devices and various features thereof are shown in U.S. Pat. No. 7,218,517 entitled “Cooling Apparatus For Vertically Stacked Printed Circuit Boards,” U.S. Pat. No. 7,535,707 entitled “Power Supply Cooling System,” U.S. Pat. No. 7,819,172 entitled “Cooling Apparatus For Vehicle Electrical Packaging Unit,” and U.S. Patent Application Publication No. 2011/0134610 entitled “Electronic Module.”

There exists a need, however, due to the high heat generated as a result of the operation of an inverter or any other electrical device with high heat generation used in automotive vehicles, for improved heat dissipation beyond that which may be provided by standard devices and/or standard methods currently in use with such devices. Such an improved electrical device and cooling method would include a printed circuit board (PCB) having multiple apertures formed therein and directing airflow substantially across a first side of the PCB so that air flows through the apertures under an electrical component on a second side of the PCB and beyond that component on the second side of the PCB.

Referring now to FIG. 1, a perspective view is shown of an inverter 50 for use in an automotive vehicle. It should be noted that the inverter 50 shown and described herein is an exemplary embodiment of the electrical device and cooling method disclosed herein. That is, the electrical device may be any device with high heat generation, and the cooling method may be used for any such device.

As seen in FIG. 1, the inverter 50 may include a printed circuit board (PCB) 10 with multiple electrical or electronic components 12, 16, 18, 20 mounted on or to at least a first side 13 of the PCB 10, which components may include a transformer 12. The transformer 12 may be cooled using an airflow having a direction shown by arrow 14. One or more additional components, such as capacitors 16 and/or other components 18, 20, may also be mounted on or to the first side 13 of the PCB 10. As can be seen, such additional components 16, 18, 20 may act to block an airflow 14 that may be used or intended to cool the transformer 12.

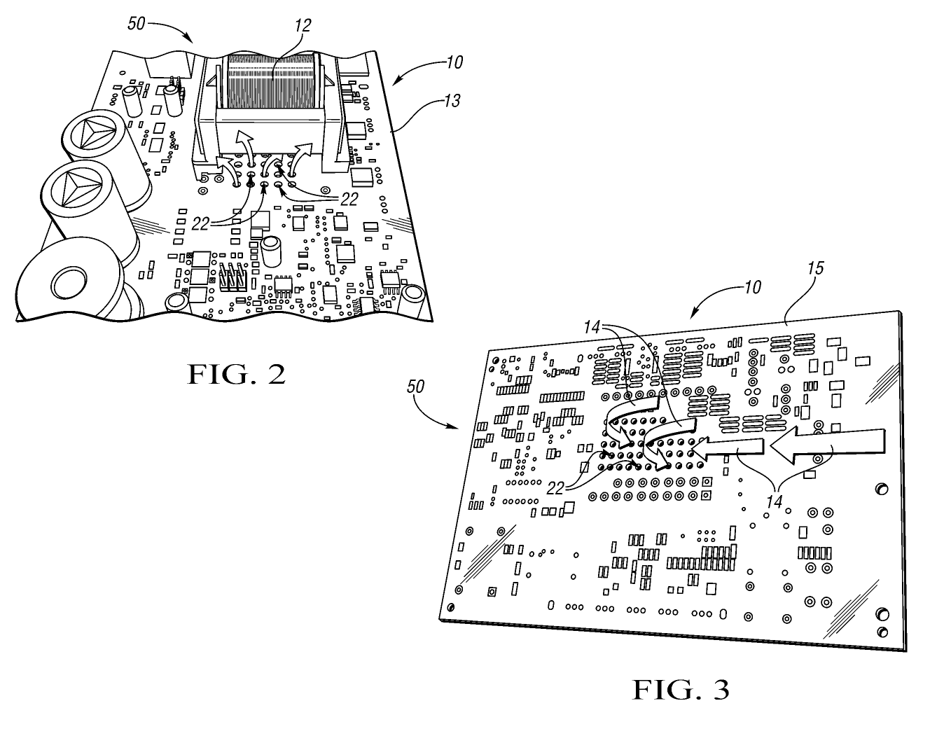

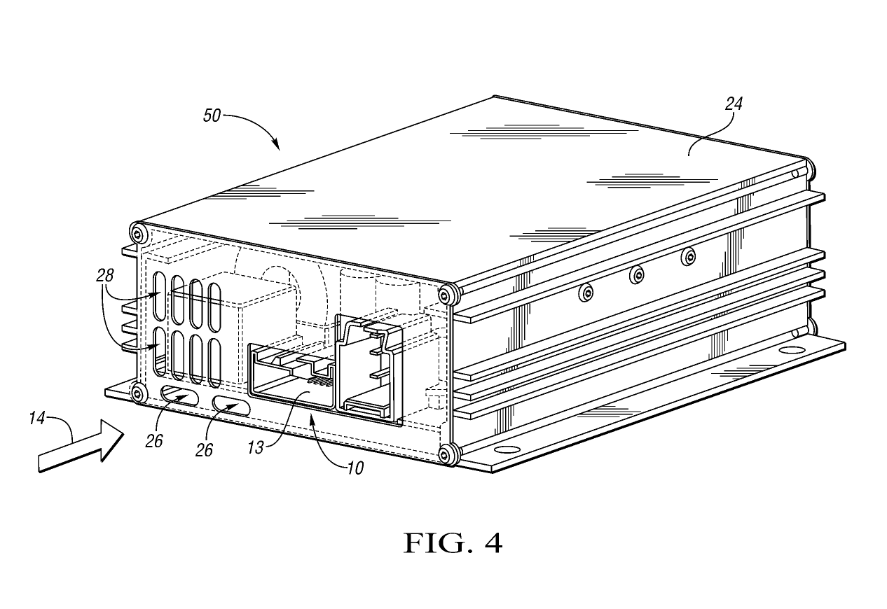

Referring next to FIGS. 2 and 3, additional perspective views are shown of an inverter 50 for use in an automotive vehicle, including a PCB 10 having apertures 22 formed therein, and multiple electrical or electronic components 12, 16, 18, 20 mounted on or to one side 13 thereof. More specifically, FIGS. 2 and 3 show perspective views of the first, top or upper side 13 of the PCB 10, and a second, bottom or lower side 15 of the PCB 10, including a plurality of apertures or holes 22 formed in or defined by the PCB 10 directly or substantially in the region of, under, or adjacent to the mounting location or position of the transformer 12 on the first side 13 of the PCB 10.

Referring next to FIG. 4, a perspective view is shown of an inverter 50 for use in an automotive vehicle, including a housing adapted 24 to receive the PCB 10 and the multiple electrical or electronic components 12, 16, 18, 20 mounted thereto. As seen therein, housing 24 may have the PCB 10 and components 12, 16, 18, 20 located inside. The housing 24 may be provided with one or more vents 26, which may be adapted, configured or designed to permit or for use in directing airflow 14 under the PCB 10 across the lower side 15 of the PCB 10 inside the housing 24. The housing 24 may also be provided with one or more additional vents 28, which may be adapted, configured or designed for use in directing, permitting or facilitating airflow over the PCB 10 across at least a portion of the upper side 13 of the PCB 10 inside the housing 24.

With reference again to FIGS. 2 and 3, airflow 14 that may be directed under the lower side 15 of the PCB 10 also flows from the bottom side 15 of the PCB 10 through the apertures or holes 22 to the upper or top side 13 of the PCB 10 and under, past and/or into contact with the transformer 12 mounted on the upper side 13 of the PCB 10 above the apertures or holes 22 and beyond the transformer 12 on the top side 13 of the PCB. In such a fashion, airflow 14 can be directed from the bottom side 15 of the PCB 10 to the transformer 12 on the top side 13 of the PCB 10 to thereby reach and/or contact and cool the transformer 12 despite the presence of components 16, 18, 20 which might otherwise block airflow directed across the upper surface 13 of the PCB 10.

In that regard, as best seen in FIGS. 1 and 2, the transformer 12 may be mounted to the PCB 10 in a spaced relation, such that an open area, space, manifold or chamber is defined between the transformer 12 and the first, upper or top surface 13 of the PCB 10. As a result, airflow 14 directed across the second, lower or bottom side 15 of the PCB 10, through the apertures 22 to the upper side 13 of the PCB 10 and under, past and/or into contact with the transformer 10 may then continue flowing on or across at least a portion of the upper side 13 of the PCB 10. As best seen in FIG. 4, in such a fashion, airflow continuing on or across the upper side 13 of the PCB 10 may be directed or permitted to travel through vents 28.

It should be noted that while the apertures 22 are shown in FIGS. 1-3 as bare and round openings in the material of the PCB 10, which may be FR4, the apertures 22 may alternatively be plated, such as with a metal or other suitable heat conducting material, and formed in other shapes or sizes. In that regard, such plating may improve heat dissipation as airflow 14 is directed or moves through the apertures 22.

It should also be noted that the second or lower side 15 of the PCB 10 is shown in FIG. 3 as devoid of electrical components such as the electrical components 12, 16, 18, 20 mounted on the first or upper side 13 of the PCB 10, in order to thereby facilitate airflow 14 across the lower side 15 of the PCB 10. However, a busbar (not shown) may optionally or alternatively be mounted on the lower side 15 of the PCB 10 without substantially inhibiting or interfering with airflow 14 across the lower side 15 of the PCB due to the low profile of such a busbar. In view of the current conducted thereby, such a busbar may thus act as a heat sink for cooling by the airflow 14 across the lower side 15 of the PCB 10.

With reference to FIGS. 1-3, it is readily apparent that an electrical device, such as an inverter 50, is disclosed for use in an automotive vehicle. The device 50 may comprise the PCB 10 having a first side 13 and a second side 15, and a plurality of electrical or electronic components 12, 16, 18, 20 mounted to the first side 13 of the PCB 10. The components may comprising a first component 12 located at a first position on the first side 13 of the PCB 10 and a second component 16 located at a second position on the first side 13 of the PCB 10. The second component 16 located at the second position may be capable of partially or substantially blocking airflow 14 directed or traveling substantially across the first side 13 of the PCB 10 in at least one direction toward the first component 12.

The PCB 10 may define or have formed therein a plurality of apertures 22. The apertures may be formed in a region of the PCB 10 comprising the first position such that airflow 14 directed substantially across the second side 15 of the PCB 10 flows through the apertures 22 into contact with the first component 12 at the first position on the first side 13 of the PCB 10.

Still referring to FIGS. 1-3, a device such as an inverter 50 for use in an automotive vehicle may alternatively comprise a PCB 10 having a first side 13 and a second side 15. The PCB 10 may be adapted for a plurality of electrical or electronic components 12, 16, 18, 20 to be mounted to the first side 13 thereof, the components comprising a first component 12 to be located at a first position on the first side 13 of the PCB 10 and a second component 16 to be located at a second position on the first side 13 of the PCB 10. The second component 16 to be located at the second position may be capable of partially or substantially blocking airflow 14 directed or traveling substantially across the first side 13 of the PCB 10 in at least one direction toward the first component 12.

The PCB 10 may define or have formed therein a plurality of apertures 22. The apertures 22 may be formed in a region of the PCB 10 comprising the first position such that airflow 14 directed substantially across the second side 15 of the PCB 10 flows through the apertures 22 under, past and/or into contact with the first component 12 at the first position on the first side 13 of the PCB 10, and beyond the region of the PCB 10 comprising the first position.

With reference again to FIG. 4, it is further apparent that the device, such as inverter 50, may further comprise housing 24, which may be adapted or configured to receive the PCB 10. The housing may further be adapted or configured to define one or more vents 26, which may be adapted or configured to permit airflow 14 to be directed across the second side 15 of the PCB 10. The housing 24 may be further configured or adapted to define one or more additional vents 28 adapted or configured to permit or facilitate airflow on or across at least a portion of the first side 13 of the PCB 10.

As best seen in FIG. 2, the plurality of apertures 22 are located in the PCB 10 substantially adjacent the first component 12 mounted to the first side 13 of the PCB 10 at the first position. As best seen in FIG. 1, the first component may comprise a transformer 12, and the second component may comprise a capacitor 16. In that regard, the second component may alternatively comprise a set of components 16, 18, 20. As best seen in FIG. 3, the second side 15 of the PCB 10 may also be entirely or substantially devoid of electrical or electronic components mounted thereto in order to facilitate the flow of air 14 substantially across the second side 15 of the PCB 10.

With reference again to FIGS. 1-4, it is also readily apparent that a method is disclosed for cooling an electrical device, such as an inverter 50, for use in an automotive vehicle. In that regard, the device 50 may once gain comprise a PCB 10 having a first side 13 and a second side 15, and a plurality of electronic components 12, 16, 18, 20 mounted to the first side of the PCB 10, the components comprising a first component 12 located at a first position on the first side 13 of the PCB 10 and a second component 16 located at a second position on the first side 13 of the PCB 10, the second component 16 located at the second position capable of partially or substantially blocking airflow 14 directed substantially across the first side 13 of the PCB 10 in at least one direction toward the first component 12, wherein the PCB 10 defines a plurality of apertures 22, the apertures 22 formed in a region of the PCB 10 comprising the first position. The method may comprise directing airflow 14 substantially across the second side 15 of the PCB 10 so that air flows through the apertures 22 under, past and/or into contact with the first component 12 at the first position on the first side 13 of the PCB 10, and beyond the region of the PCB 10 comprising the first position.

Here again, according to the method for cooling an electrical device 50, the inverter 50 may further comprises a housing 24, which may be configured to receive the PCB 10, the housing 24 defining one or more vents 26 configured to permit airflow 14 to be directed across the second side 15 of the PCB 10. The housing 24 may further define one or more additional vents 28 configured to permit or facilitate airflow 14 on or across at least a portion of the first side 13 of the PCB 10. As well, the plurality of apertures 22 may be located directly or substantially adjacent the first component 12 mounted to the first side 13 of the PCB 10 at the first position.

As is readily apparent from the foregoing, an electrical device for use in an automotive vehicle and a method for cooling such a device have been described. The embodiments of the device and method described provide for improved heat dissipation beyond that which may be supplied by standard devices and/or methods used such devices. Such embodiments include a printed circuit board (PCB) having multiple apertures formed therein and directing airflow substantially across one side of the PCB so that air flows through the apertures past or into contact with an electrical component on the other side of the PCB.

While various embodiments of an electrical device for use in an automotive vehicle and a method for cooling such a device have been illustrated and described herein, they are exemplary only and it is not intended that these embodiments illustrate and describe all those possible. Instead, the words used herein are words of description rather than limitation, and it is understood that various changes may be made to these embodiments without departing from the spirit and scope of the following claims.

What is claimed is:

1. An electrical device for use in an automotive vehicle, the device comprising:
a printed circuit board (PCB) having a first side and a second side; and
a plurality of electronic components mounted to the first side of the PCB, the components comprising a first component located at a first position on the first side of the PCB and a second component located at a second position on the first side of the PCB, the second component located at the second position capable of at least partially blocking airflow directed substantially across the first side of the PCB in at least one direction toward the first component;
wherein the PCB defines a plurality of apertures therethrough, the apertures formed in a region of the PCB comprising the first position such that airflow directed substantially across the second side of the PCB flows through the apertures, under the first component at the first position on the first side of the PCB, and on at least a portion of the first side of the PCB beyond the region of the PCB comprising the first position.

2. The device of claim 1 further comprising a housing configured to receive the PCB, the housing defining a vent configured to permit airflow to be directed across the second side of the PCB.

3. The device of claim 2 wherein the housing defines an additional vent configured to facilitate airflow on the first side of the PCB.

4. The device of claim 1 wherein the plurality of apertures are located substantially adjacent the first component mounted to the first side of the PCB at the first position.

5. The device of claim 1 wherein the first component comprises a transformer.

6. The device of claim 1 wherein the second component comprises a capacitor.

7. The device of claim 1 wherein the second component comprises a set of components.

8. The device of claim 1 wherein the second side of the PCB is devoid of electronic components mounted thereto to facilitate airflow across the second side of the PCB.

9. An electrical device for use in an automotive vehicle, the inverter comprising:
a printed circuit board (PCB) having a first side and a second side, the PCB adapted for a plurality of electronic components to be mounted to the first side thereof, the components comprising a first component to be located at a first position on the first side of the PCB and a second component to be located at a second position on the first side of the PCB, the second component to be located at the second position capable of at least partially blocking airflow directed substantially across the first side of the PCB in at least one direction toward the first component;
wherein the PCB defines a plurality of apertures therethrough, the apertures formed in a region of the PCB comprising the first position such that airflow directed substantially across the second side of the PCB flows through the apertures, under the first component at the first position on the first side of the PCB, and on at least a portion of the first side of the PCB beyond the region of the PCB comprising the first position.

10. The device of claim 9 further comprising a housing configured to receive the PCB, the housing defining a vent configured to permit airflow to be directed across the second side of the PCB.

11. The device of claim 10 wherein the housing defines an additional vent configured to facilitate airflow on the first side of the PCB.

12. The device of claim 9 wherein the plurality of apertures are located substantially adjacent the first component to be mounted to the first side of the PCB at the first position.

13. The device of claim 9 wherein the first component comprises a transformer.

14. The device of claim 9 wherein the second component comprises a capacitor.

15. The device of claim 9 wherein the second component comprises a set of components.

16. The device of claim 9 wherein the second side of the PCB has a busbar mounted thereto, the busbar to be cooled by airflow across the second side of the PCB.

17. A method for cooling an electrical device for use in an automotive vehicle, the device comprising a printed circuit board (PCB) having a first side and a second side, and a plurality of electronic components mounted to the first side of the PCB, the components comprising a first component located at a first position on the first side of the PCB and a second component located at a second position on the first side of the PCB, the second component located at the second position capable of at least partially blocking airflow directed substantially across the first side of the PCB in at least one direction toward the first component, wherein the PCB defines a plurality of apertures therethrough, the apertures formed in a region of the PCB comprising the first position, the method comprising:
directing airflow substantially across the second side of the PCB so that air flows through the apertures, under the first component at the first position on the first side of the PCB, and on at least a portion of the first side of the PCB beyond the region of the PCB comprising the first position.

18. The method of claim 17 wherein the device further comprises a housing configured to receive the PCB, the housing defining a vent configured to permit airflow to be directed across the second side of the PCB.

19. The method of claim 18 wherein the housing defines an additional vent configured to facilitate airflow on the first side of the PCB.

20. The method of claim 17 wherein the plurality of apertures are located substantially adjacent the first component mounted to the first side of the PCB at the first position.
